(19) United States
(12) Patent Application Publication
(10) Pub. No.: US 2017/0179058 A1
(43) Pub. Date: Jun. 22, 2017

(54) BUMP STRUCTURE HAVING FIRST PORTION OF COPPER AND SECOND PORTION OF PURE TIN COVERING THE FIRST PORTION, AND INTERCONNECT STRUCTURE USING THE SAME

(71) Applicant: LITE-ON SEMICONDUCTOR CORPORATION, New Taipei City (TW)

(72) Inventor: Bai-Yao Lou, Taipei City (TW)

(21) Appl. No.: 14/970,552

(22) Filed: Dec. 16, 2015

(51) Int. Cl. H01L 23/00

(52) U.S. Cl. CPC H01L 24/13; H01L 2224/13026; H01L 2224/13082; H01L 2224/13111; H01L 2224/13147

(57) ABSTRACT

A bump structure includes a pad. A passivation layer covers a perimeter of the pad. The passivation layer includes an opening exposing an area of the pad. A first portion is disposed on the pad. The first portion includes a top surface and a sidewall. A second portion covers the top surface and entire sidewall of the first portion.

### BACKGROUND OF THE INVENTION

1. Field of the Invention

The present invention relates generally to bumping technology. More particularly, the present invention relates to a bump structure and an interconnect structure between a semiconductor chip (or a wafer) and a substrate utilizing such bump structure, which are suited for fine-pitch three-dimensional (3D) flip-chip bonding or 3D integrated circuit (IC) packaging applications.

2. Description of the Prior Art

As known in the art, flip chip is a method for interconnecting semiconductor devices, such as IC chips, to external circuitry with solder bumps that are deposited onto the chip pads. The solder bumps are deposited on the chip pads on the top side of the wafer during the final wafer-processing step. In order to mount the chip to external circuitry (e.g., a circuit board or another chip or wafer), it is flipped over so that its top side faces down, and aligned so that its pads align with matching pads on the external circuit, and then the solder is reflowed to complete the interconnect.

The flip-chip on BGA method generally involves flipping a bumped die onto a BGA substrate, underfilling, molding, ball attachment, and singulation. Solder ball dimension continues to shrink to increase the density of contacts. For example, balls with a diameter of 0.5 mm and a pitch of 1 mm are currently in use for ball grid arrays (BGAs) for the connection of the package to the board. Microbumps, which are used inside the packages, usually have diameters below 100 micrometers.

Flip chip packaging used to be the domain of microprocessors and ASICs. Application processors were next to adopt flip chip packaging in high volume. This type of packaging was based on solder interconnects, typically PbSn eutectic solder on organic substrates. In order to solve electro migration issues, micro-processors adopted copper (Cu) pillars. Flip chip packages are now also adopting Cu pillars primarily as a fine pitch solution. Cu pillars can be formed as slender columns, which can maintain their initial shape during assembly unlike solder.

Typically, a predetermined amount of solder is deposited on the free ends of the Cu pillars. The solder is coated with flux. After reflowed, the solder melts and with the assistance of the flux forms solder interconnects between the free ends of the Cu pillars on the semiconductor die and the interconnect locations on a substrate.

### SUMMARY OF THE INVENTION

It is one objective to provide an improved copper pillar bump structure and an interconnect structure between a semiconductor chip and a substrate utilizing such copper pillar bump structure, which are suited for fine-pitch three-dimensional (3D) flip-chip bonding or 3D integrated circuit (IC) packaging applications.

According to one aspect, the invention provides a bump structure including a pad; a passivation layer covering a perimeter of the pad, wherein the passivation layer comprises an opening exposing an area of the pad; a first portion on the pad, the first portion comprising a top surface and a sidewall; and a second portion covering the top surface and entire sidewall of the first portion.

According to one embodiment, the second portion is in direct contact with the passivation layer.

According to one embodiment, the pad is a metal pad and the first portion comprises copper. According to one embodiment, the second portion comprises pure tin. The metal pad comprises Cu, AlCu, or AlSiCu.

According to another aspect, the invention provides an interconnect structure for electrically connecting a semiconductor die to a substrate, including a first portion extending between the semiconductor die and a contact surface of the substrate; a second portion covering an entire sidewall of the first portion; and an interfacial layer between the first portion and the contact surface of the substrate. The interfacial layer consists purely of a copper-tin intermetallic compound.

According to one embodiment, the copper-tin intermetallic compound comprises Cu₆Sn₅, Cu₃Sn, or a combination thereof. The substrate comprises an organic substrate, a leadframe, or a wafer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute apart of this specification. The drawings illustrate some of the embodiments and, together with the description, serve to explain their principles. In the drawings:

FIG. 1 is a schematic, cross-sectional diagram showing an interconnect structure between a semiconductor die and a substrate according to one embodiment of the invention;

FIG. 2 is a schematic, cross-sectional diagram showing a bump structure in accordance with one embodiment of the invention;

FIG. 3 to FIG. 7 are schematic, cross-sectional diagrams showing an exemplary method for fabricating the bump structure of FIG. 2 according to the invention; and

FIG. 8 is a schematic, cross-sectional diagram showing a bump structure with solder cap in accordance with another embodiment of the invention.

It should be noted that all the figures are diagrammatic. Relative dimensions and proportions of parts of the drawings are exaggerated or reduced in size, for the sake of clarity and convenience. The same reference signs are generally used to refer to corresponding or similar features in modified and different embodiments.

### DETAILED DESCRIPTION

In the following description, numerous specific details are given to provide a thorough understanding of the invention. It will, however, be apparent to one skilled in the art that the invention may be practiced without these specific details. Furthermore, some well-known configurations and process steps are not disclosed in detail, as these should be well-known to those skilled in the art.

Likewise, the drawings showing embodiments of the device are semi-diagrammatic and not to scale and some dimensions are exaggerated in the figures for clarity of presentation. Also, where multiple embodiments are disclosed and described as having some features in common, like or similar features will usually be described with like reference numerals for ease of illustration and description thereof.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising” when used in this specification, specify the presence of stated features, integers, steps, operations, elements, and/ or components, but do not preclude the presence or addition of one or more other features, integers, steps, operations, elements, components, and/or groups thereof. It will be further understood that the terms “die”, “semiconductor chip”, and “semiconductor die” are used interchangeable throughout the specification.

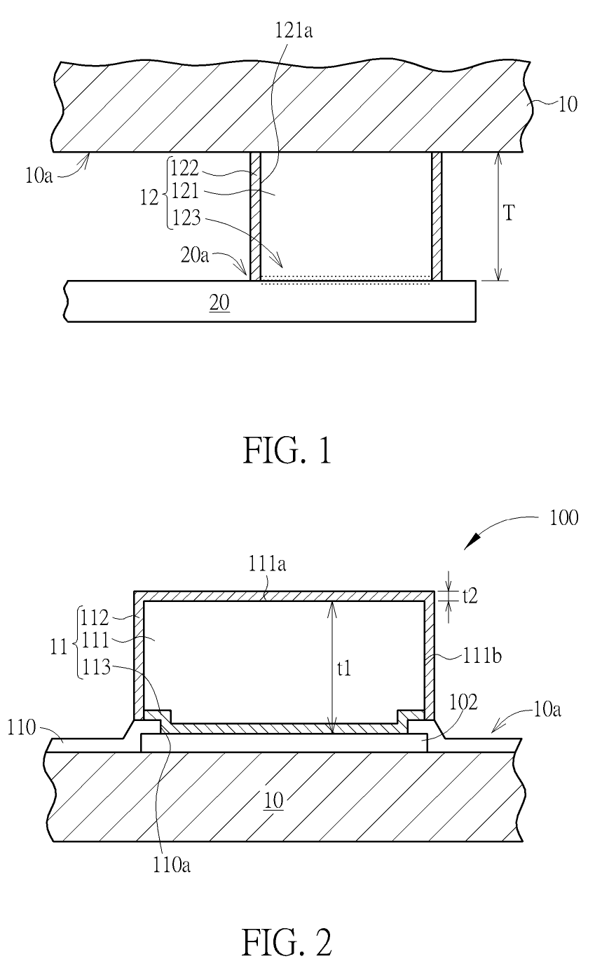

FIG. 1 is a schematic, cross-sectional diagram showing a germane portion of a semiconductor package including an interconnect structure 12 for electrically connecting a semiconductor die (or wafer) 10 to a substrate 20 according to one embodiment of the invention. As shown in FIG. 1, the semiconductor die 10 is electrically connected to the substrate 20 through an interconnect structure 12. According to one embodiment of the invention, the substrate 20 may comprise an organic substrate, a leadframe substrate, a wafer, a packaging substrate, a package, a chip, a circuit substrate or board, but is not limited thereto. The substrate 20 comprises a suitable contact surface 20a that matches and receives the interconnect structure 12.

According to one embodiment of the invention, the interconnect structure 12 has a height or a thickness T that is less than or equal to 50 micrometers. In some embodiments, a molding compound (not shown) may be formed between the semiconductor die 10 and the substrate 20 and surrounds the interconnect structure 12. According to one embodiment of the invention, no solder is used. Therefore, a reflow process that is typically used to reflow the solder can be omitted.

It is understood that in some embodiments, the semiconductor die 10 may not be a flipped die. For example, in some embodiments, the semiconductor die 10 may be an image sensor chip and the interconnect structure 12 is used to electrically connect pads disposed on the backside of the image sensor chip to the contact surface 20a of the substrate 20. In addition to the illustrated die-to-wafer configuration, the interconnect structure 12 may be applicable to wafer-to-wafer bonding. In wafer-to-wafer bonding, the semiconductor die 10 is replaced with a wafer.

According to one embodiment of the invention, for example, the suitable contact surface 20a on the substrate 20 may be a copper (Cu) pad surface having an exposed copper surface. According to one embodiment of the invention, for example, the suitable contact surface 20a on the substrate 20 may be temporarily covered with a surface finish layer such as an organic solderability preservatives (OSP) to avoid oxidation of the contact surface 20a before assembly. Suitable OSP may be based on benzotriazoles, benzimidazoles, and their respective derivatives. According to one embodiment of the invention, the surface finish layer does not comprise Ni/Au.

According to one embodiment of the invention, the interconnect structure 12 includes a first portion 121 extending between a surface 10a of the semiconductor die 10 and the contact surface 20a of the substrate 20. According to one embodiment of the invention, the surface 10a may be an active surface of the semiconductor die 10. The semiconductor die 10 is flipped such that its active surface faces the contact surface of the substrate. According to another embodiment of the invention, the surface 10a may be a backside surface of the semiconductor die 10.

According to one embodiment of the invention, the first portion 121 may be composed of a homogeneous first material. The first material comprises conductive materials. For example, the first portion 121 may consist purely of copper in a pillar form and may be formed by electroplating methods. The first portion 121 may be disposed directly on a conductive pad (not explicitly shown in this figure) disposed on the surface 10a. It is understood that the surface 10a may be covered with a passivation layer (not explicitly shown in this figure), but is not limited thereto.

According to one embodiment of the invention, the first portion 121 includes vertical sidewalls 121a. According to one embodiment of the invention, the entire sidewall 121a is covered with a second portion 122. According to one embodiment of the invention, the second portion 122 may be composed of a homogeneous second material. According to one embodiment of the invention, the second material may comprise conductive materials such as metal elements, but is not limited thereto. According to one embodiment of the invention, for example, the second portion 122 may consist of pure tin (Sn) and may be formed by electroless plating, immersion or dipping methods, but is not limited thereto. According to one embodiment of the invention, the second portion 122 may have a thickness that is less than or equal to 10 micrometers.

The second portion 122 protects the sidewall 121a of the first portion 121 from oxidation and may enable wetting of the first portion 121. The second portion 122 may be formed by other suitable methods, for example, an electroplating process, a vacuum evaporation process, a sputtering process, or a chemical vapor deposition process. In a case that the surface 10a of the semiconductor die 10 is covered by a passivation layer, the second portion 122 may be in direct contact with the passivation layer.

According to one embodiment of the invention, the interconnect structure 12 further comprises a third portion 123 located at the interface between the first portion 121 and the contact surface 20a. According to one embodiment of the invention, the third portion 123 is a thin interfacial layer consisting purely of a copper-tin intermetallic compound that is formed by reacting copper of the first portion 121 and copper of the contact surface 20a with a thin, pure tin layer initially disposed between the first portion 121 and the contact surface 20a. The thin, pure tin layer that was initially disposed between the first portion 121 and the contact surface 20a is totally consumed later in a thermo-compression process or an anneal process at a temperature of, for example, about 260° C. to 300° C., thereby forming the copper-tin intermetallic compound. According to one embodiment of the invention, the formed copper-tin intermetallic compound may comprise Cu₆Sn₅, Cu₃Sn, or a combination thereof, but is not limited thereto. The third portion 123 creates a reliable and strong bonding between the first portion (copper pillar) 121 and the contact surface 20a of the substrate 20.

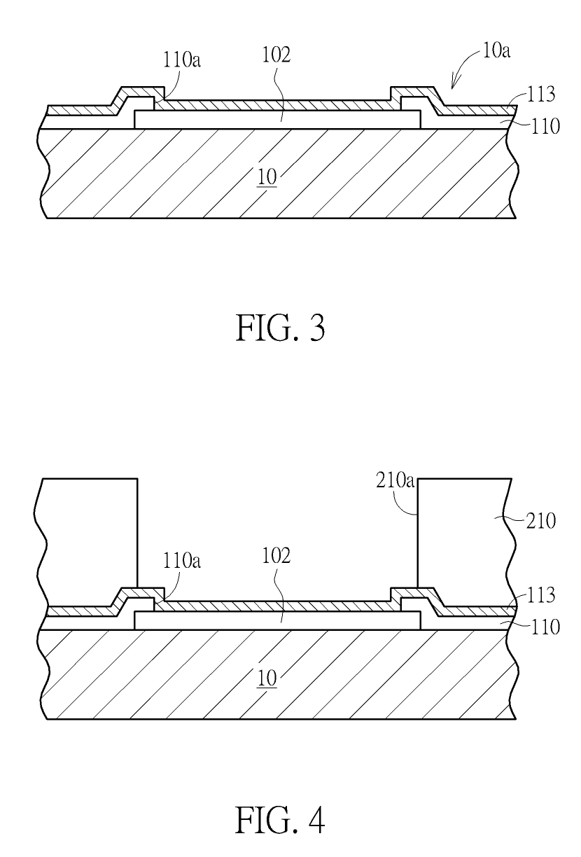

FIG. 2 is a schematic, cross-sectional diagram showing a semiconductor device 100 including a bump structure 11 in accordance with another embodiment of the invention. As shown in FIG. 2, the semiconductor device 100 comprises a semiconductor die 10 with its surface 10a covered by a passivation layer 110. According to one embodiment of the invention, for example, the passivation layer 110 may comprise silicon oxide, silicon nitride, or polyimide, but is not limited thereto. A bump pad 102 is formed on the surface 10a of the semiconductor die 10. According to one embodiment of the invention, the bump pad 102 is a metal pad, for example, a copper pad. Typically, the perimeter of the bump pad 102 is covered with the passivation layer 110 and a central area of the bump pad 102 is exposed through an opening 110a in the passivation layer 110. A bump structure 11 is formed on bump pad 102 through the opening 110a.

According to one embodiment of the invention, the bump structure 11 comprises a first portion (copper pillar) 111 and a second portion (cap layer) 112 conformally covering a top surface 111a of the first portion 111 and a sidewall 111b of the first portion 111. According to one embodiment of the invention, the bump structure 11 may further comprise an under-bump-metallurgy (UBM) layer 113 interposed between the first portion 111 and the bump pad 102. According to one embodiment of the invention, the first portion 111 may consist purely of copper, but is not limited thereto. According to one embodiment of the invention, the second portion 112 may consist purely of tin (pure tin) formed by electroless plating processes, but is not limited thereto. According to one embodiment of the invention, the second portion 112 conformally covers the entire sidewall 111b of the first portion 111. According to one embodiment of the invention, the second portion 112 is in direct contact with the passivation layer 110.

According to another embodiment of the invention, the second portion 112 may be independently selected from the group consisting of Ni/Au, NiPdAu, Ni/Ag, Au, tin-lead alloy, silver, organic solderability preservatives (OSPs), and combination thereof. Suitable OSPs are based on benzotriazoles, benzimidazoles, and their respective derivatives.

In some embodiments, the UBM layer 113 may include a diffusion barrier layer (or a glue layer), which may comprise titanium, tantalum, titanium nitride, tantalum nitride, or the like. According to another embodiment of the invention, the diffusion barrier layer may be deposited to a thickness of between about 500 and 2000 angstroms, but is not limited thereto. In some embodiments, the UBM layer 113 may further include a seed layer such as copper or copper alloys. According to another embodiment of the invention, the seed layer may be deposited to a thickness of between about 500 and 10000 angstroms, but is not limited thereto. According to one embodiment of the invention, the first portion 111 and the UBM layer 113 has a combined thickness t1, wherein, for example, t1 is less than or equal to 45 micrometers. According to one embodiment of the invention, the second portion 112 has a thickness t2, wherein, for example, t2 may range between 1 micrometer and 10 micrometers, and the combined thickness of t1 and t2 is less than or equal to 50 micrometers.

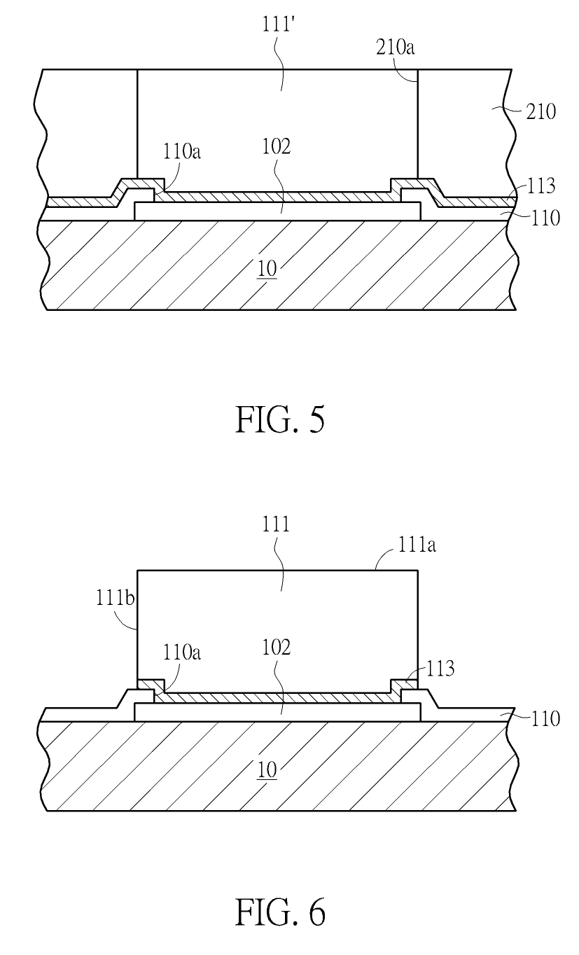

FIG. 3 to FIG. 7 are schematic, cross-sectional diagrams showing an exemplary method for fabricating the bump structure of FIG. 2 according to the invention. As shown in FIG. 3, a semiconductor die 10 is provided. Although not shown in the figures, it is understood that a plurality of semiconductor components such as metal-oxide-semiconductor (MOS) transistors and circuit structures such as metal interconnection structures may be formed in the semiconductor die 10. The semiconductor die 10 has a surface 10a that is covered by a passivation layer 110.

According to one embodiment of the invention, the passivation layer 110 may be the topmost dielectric layer of the semiconductor die 10, but is not limited thereto. According to one embodiment of the invention, for example, the passivation layer 110 may comprise silicon oxide, silicon nitride, or polyimide, but is not limited thereto. A bump pad 102 is formed on the surface 10a of the semiconductor die 10. According to one embodiment of the invention, the bump pad 102 is a metal pad, preferably a copper pad. According to one embodiment of the invention, the bump pad 102 may be the topmost metal layer of the semiconductor die 10, but is not limited thereto. Typically, the perimeter of the bump pad 102 is covered with the passivation layer 110 and an area of the bump pad 102 is exposed through an opening 110a in the passivation layer 110.

The opening 110a may be formed by using lithographic processes and etching processes known in the art. After forming the opening 110a, an under-bump-metallurgy (UBM) layer 113 is deposited on the surface 10a in a blanket manner. The UBM layer 113 conformally covers the passivation layer 110, the opening 110a, and the exposed surface of the bump pad 102. For example, the UBM layer 113 may include a diffusion barrier layer (or a glue layer), which may comprise titanium, tantalum, titanium nitride, tantalum nitride, or the like. According to another embodiment of the invention, the diffusion barrier layer may be deposited to a thickness of between about 500 and 2000 angstroms, but is not limited thereto. In some embodiments, the UBM layer 113 may further include a seed layer such as copper or copper alloys. According to another embodiment of the invention, the seed layer may be deposited to a thickness of between about 500 and 10000 angstroms, but is not limited thereto.

As shown in FIG. 4, a patterned photoresist layer (or a mask layer) 210 is then formed on the surface 10a. The patterned photoresist layer 210 includes an opening 210a that is substantially aligned with the bump pad 102. The patterned photoresist layer 210 and the opening 210a may be formed by using lithographic processes known in the art. According to another embodiment of the invention, the patterned photoresist layer 210 has a thickness that is substantially equal to the thickness of the copper bump or copper pillar to be formed within the opening 210a.

As shown in FIG. 5, a plating process is then performed to fill the opening 210a with a plated metal layer 111′ such as copper. For example, the plated metal layer 111′ may be deposited by using an electro-chemical deposition (ECD) process, but is not limited thereto. According to one embodiment of the invention, the plated metal layer 111′ may be preferably formed to a thickness ranging between about 40 micrometers and about 50 micrometers. However, it will be appreciated that the plated metal layer 111′ may be formed by an electroless, CVD or PVD method.

As shown in FIG. 6, after the plating process is completed, the patterned photoresist layer 210 is removed to reveal a top surface of the UBM layer 113, thereby forming a copper pillar 111. Subsequently, the UBM layer 113 not covered by the copper pillar 111 is removed. The UBM layer 113 may be removed in a self-aligned manner by using a wet etching process or a dry etching process known in the art. The copper pillar 111 includes a top surface 111a and sidewall 111b.

As shown in FIG. 7, subsequently, an electroless plating process may be performed to cover the top surface 111a and sidewall 111b of the copper pillar 111 with a conformal cap layer 112. According to one embodiment of the invention, the cap layer 112 may consist purely of tin (pure tin). According to another embodiment of the invention, the cap layer 112 may be independently selected from the group consisting of Ni/Au, NiPdAu, Ni/Ag, Au, tin-lead alloy, silver, organic solderability preservatives (OSPs), and combination thereof. Suitable OSPs are based on benzotriazoles, benzimidazoles, and their respective derivatives. According to one embodiment of the invention, the cap layer 112 has a thickness ranging between 1 micrometer and 10 micrometers.

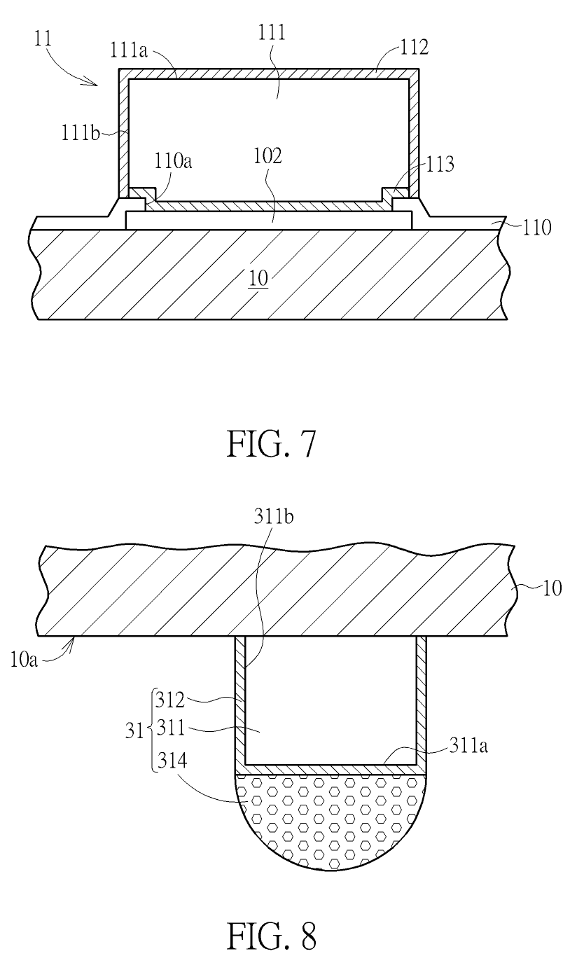

FIG. 8 is a schematic, cross-sectional diagram showing a bump structure with solder cap in accordance with another embodiment of the invention, wherein like numeral numbers designate like regions, layers, or elements. As shown in FIG. 8, a bump structure 31 is disposed on a surface 10a of the semiconductor die 10. The bump structure 31 comprises a copper pillar 311 protruding from the surface 10a. The copper pillar 311 has a top surface 311a and sidewall 311b. A conformal cap layer 312 is deposited on the top surface 311a and sidewall 311b. The cap layer 312 may be independently selected from the group consisting of Ni/Au, NiPdAu, Ni/Ag, Au, tin-lead alloy, silver, organic solderability preservatives (OSPs), and combination thereof. Suitable OSPs are based on benzotriazoles, benzimidazoles, and their respective derivatives. According to one embodiment of the invention, the cap layer 312 has a thickness ranging between 1 micrometer and 10 micrometers. The bump structure 31 further comprises a solder cap 314 having a predetermined volume, which is disposed directly on the cap layer 312 and is adjacent to the distal end of the copper pillar 311. The solder cap 314 may comprises reflowable and solderable materials including, but not limited to, tin lead eutectic solder or Pb-free solder.

Those skilled in the art will readily observe that numerous modifications and alterations of the device and method may be made while retaining the teachings of the invention. Accordingly, the above disclosure should be construed as limited only by the metes and bounds of the appended claims.

1. A bump structure, comprising:
a pad;
a passivation layer covering a perimeter of said pad, wherein said passivation layer comprises an opening exposing an area of said pad;
a first portion on said pad, said first portion comprising a top surface and a sidewall, wherein said first portion comprises copper; and
a second portion covering said top surface and entire said sidewall, wherein said second portion comprises pure tin.

2. The bump structure according to claim 1, wherein said second portion is in direct contact with said passivation layer.

3. The bump structure according to claim 1, wherein said pad is a metal pad.

4. The bump structure according to claim 3, wherein said metal pad comprises Cu, AlCu, or AlSiCu.

5-7. (canceled)

8. The bump structure according to claim 1, wherein said second portion has a thickness ranging between 1 micrometer and 10 micrometers.

9. An interconnect structure for electrically connecting a semiconductor die to a substrate, comprising:
a first portion extending between said semiconductor die and a contact surface of said substrate;
a second portion covering an entire sidewall of said first portion; and
an interfacial layer between said first portion and said contact surface of said substrate, wherein said interfacial layer consists purely of a copper-tin intermetallic compound, wherein said interfacial layer is in direct contact with said first portion and is in direct contact with said contact surface of said substrate.

10. The interconnect structure according to claim 9, wherein said substrate comprises an organic substrate, a leadframe, or a wafer.

11. The interconnect structure according to claim 9, wherein said copper-tin intermetallic compound comprises Cu₆Sn₅, Cu₃Sn, or a combination thereof.

12. The interconnect structure according to claim 9, wherein said first portion is composed of a homogeneous first material and said second portion is composed of a homogeneous second material.

13. The interconnect structure according to claim 12, wherein said homogeneous first material comprises copper.

14. The interconnect structure according to claim 12, wherein said homogeneous second material comprises a metal element.

15. The interconnect structure according to claim 14, wherein said metal element is pure tin.

16. The interconnect structure according to claim 14, wherein said second portion has a thickness ranging between 1 micrometer and 10 micrometers.

17. An interconnect structure for electrically connecting two wafers, comprising:
a first portion extending between a first wafer and a second wafer;
a second portion covering an entire sidewall of said first portion; and
an interfacial layer between said first portion and a contact surface of either said first wafer or said second wafer, wherein said interfacial layer consists purely of a copper-tin intermetallic compound, wherein said interfacial layer is in direct contact with said first portion and is in direct contact with said contact surface of either said first wafer or said second wafer.
